(19) United States
(12) Patent Application Publication
(10) Pub. No.: US 2024/0108066 A1
(43) Pub. Date: Apr. 4, 2024

(54) An Aerosol-Generating Device Comprising a Heater

(71) Applicant: JT International SA, Geneva (CH)

(72) Inventors: Alec Wright, Guildford (GB); Andrew Robert John Rogan, Forres (GB); Kyle Adair, Lisburn (GB); Gordon Montgomery, Ballymena (GB)

(73) Assignee: JT International SA, Geneva (CH)

(21) Appl. No.: 18/275,537

(22) PCT Filed: Feb. 2, 2022
(86) PCT No.: PCT/EP2022/052488

§ 371 Date: Aug. 2, 2023

(30) Foreign Application Priority Data
Feb. 4, 2021 (EP) 21155258.3

(51) Int. Cl. A24F 40/46; A24F 40/42

(52) U.S. Cl. CPC A24F 40/46; A24F 40/42; A24F 40/485

(57) ABSTRACT

An aerosol-generating device includes a vapor generation unit and a reservoir configured to store an aerosolizable material. The aerosol-generation device further includes a printed circuit board and a heater fastened to the printed circuit board, the printed circuit board being disposed such that the aerosolizable material is in contact with the printed circuit board after it derives from the reservoir and before it arrives to the vapor generation unit.

### FIELD OF THE INVENTION

The present invention relates to an aerosol-generating device.

An aerosol-generating device allows aerosolization of an aerosolizable material. An aerosol-generating device can also be referred to as an electronic cigarette or vapor generation device.

### BACKGROUND OF THE INVENTION

An aerosol-generating device generally comprises a battery-powered vapor generation unit which produces the aerosol that is inhaled. For this purpose, many vapor generation units have been designed in prior art, among which microfluidic devices or more generally units comprising a micro-electro-mechanical-systems (MEMS). Document US2020008473 discloses for instance an electronic cigarette comprising a MEMS.

The MEMS technology can be defined as micro electro-mechanical systems that are made using the techniques of micro fabrication. MEMS technology is also referred to as microsystem technology (MST) in Europe.

The vapor generation units comprising a MEMS present many advantages, in particular in size and power consumption. However, aerosol-generating devices comprising such a vapor generation unit do not usually produce warm aerosol as the aerosolizable material does not undergo phase changes before vaporization. Therefore, the produced aerosol is at ambient temperature or as low as 1° Celsius above the ambient temperature. This is because a small amount of the aerosolizable material goes through a phase change during aerosol generation and gets heated to boiling point. Inhaling a cold aerosol could be odd for the consumer who generally used to inhale warm aerosol.

Therefore, the present invention aims at improving the user experience by providing an aerosol-generating device comprising a vapor generating unit comprising a MEMS and capable of producing warm aerosol without increasing the size of the aerosol-generating device and in a cost-efficient way.

### SUMMARY OF THE INVENTION

The present invention thus relates to an aerosol-generating device comprising a vapor generation unit and a reservoir configured to store an aerosolizable material, the vapor generation unit comprising a micro electro-mechanical system (MEMS).

According to the invention, the aerosol-generating device further comprises a printed circuit board and a heater fastened to said printed circuit board, the printed circuit board being disposed such that the aerosolizable material is in contact with said printed circuit board after it derives from the reservoir and before it arrives to the vapor generation unit, the printed circuit board comprising at least two stacked boards and a spacer between two of said boards, said boards and said spacer being attached to each other so as to form a void configured to receive the aerosolizable material deriving from the reservoir.

Thanks to this configuration, it is possible to provide warm vapor to the consumer of a vapor generation unit type aerosol-generating device in an easy, inexpensive and compact way. Moreover, heating the aerosolizable material before its passage into the vapor generation unit helps improving the user experience.

According to one embodiment, the heater comprises a resistive layer adapted to be heated when power is applied to it.

According to one embodiment, the heater is a heating film.

The heating film is a solution for heating that presents many advantages as it is easy to implement, provides a fast heating and is economical.

According to one embodiment, the heater comprises a coating layer made of a material adapted to prevent chemical reactions with the aerosolizable material.

According to one embodiment, the coating layer is made of gold or silver.

Gold and silver present moreover the advantage to have a high thermal conductivity.

According to one embodiment, the vapor generation unit is mounted on the printed circuit board.

The vapor generation unit is thus close to the heater which is fastened to the printed circuit board. Thanks to this feature, temperature drop of the aerosolizable material before it reaches the vapor generation unit is reduced as much as possible.

According to one embodiment, the printed circuit board comprises two stacked boards, namely a daughterboard and a cover board.

According to one embodiment, the heater is mounted on the cover board.

According to one embodiment, the heater matches the dimensions and the shape of said void.

This enables an optimized heating of the aerosolizable material.

According to one embodiment, the vapor generation unit is mounted on the daughterboard, the daughterboard being configured to provide an exit for the aerosolizable material.

### BRIEF DESCRIPTION OF THE DRAWINGS

Other particularities and advantages of the invention will also emerge from the following description.

In the accompanying drawings, given by way of non-limiting examples:

FIG. 1 represents, in a schematic three-dimensional view, an aerosol-generating device according to an embodiment of the invention;

FIG. 2a represents, in a schematic three-dimensional view, an example of a vapor generation unit that can be used in the invention;

FIG. 2b represents in a cross-sectional diagram a portion of an example of an aerosol-generation device comprising a vapor generation units that can be used in the invention;

FIG. 3 represents, in a schematic cross-sectional view of a printed circuit board and a heater of the aerosol-generating device according to an embodiment of the invention; and

FIG. 4 represents a top view of the heater mounted on the printed circuit board of FIG. 3.

### DETAILED DESCRIPTION

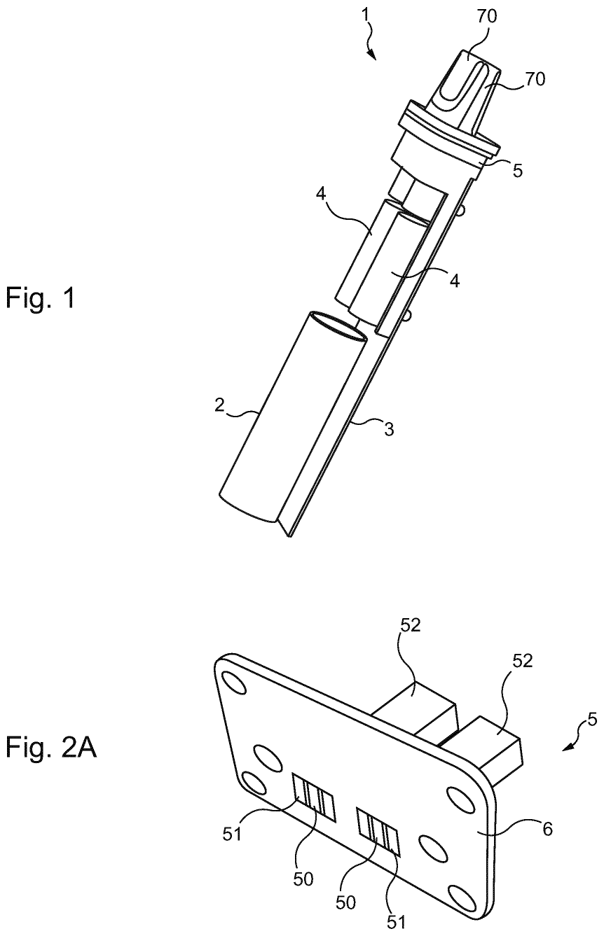

FIG. 1 represents schematically part of an aerosol-generating device 1 according to one embodiment of the invention. The device is normally covered with a casing omitted here to show the inner parts of the aerosol-generating device.

The aerosol-generating device 1 comprises a battery 2 or power supply unit adapted to supply power to electronic components of the device.

The aerosol-generating device 1 also comprises a main printed circuit board 3.

The battery 2 is fastened to the main printed circuit board 3 of the aerosol-generating device. The main printed circuit board 3 constitutes the main support structure for various elements of the aerosol-generating device.

The aerosol-generating device 1 further comprises at least one reservoir 4. The reservoir 4 is arranged to store an aerosolizable material.

The term aerosolizable material is used to designate any material that is aerosolizable in air to form an aerosol. The aerosolizable material may, for example, be in liquid form (called e-liquid), in solid form, or in a semi liquid form. The aerosolizable material thus comprises or consists of an aerosol-generating liquid, gel, paste or wax or the like, or any combination of these. E-liquid is mostly a mix of water, propylene glycol (PG), and vegetable glycerine or glycerol (VG).

The reservoir 4 forms a removable component that can be detached from the aerosol-generating device 1 (such as when the reservoir is empty of liquid). However, the reservoir can also be permanently installed on the aerosol-generating device if it is configured to be refillable.

In the represented embodiment, the aerosol-generating device 1 comprises two reservoirs 4. The reservoirs 4 are formed here by two hollow tubes.

The reservoir 4 can be, by way of example, a one-piece plastic part, for example obtained by injection molding.

The aerosol-generating device 1 also comprises a vapor generation unit 5 arranged to aerosolize the product received from the reservoir in order to generate aerosol.

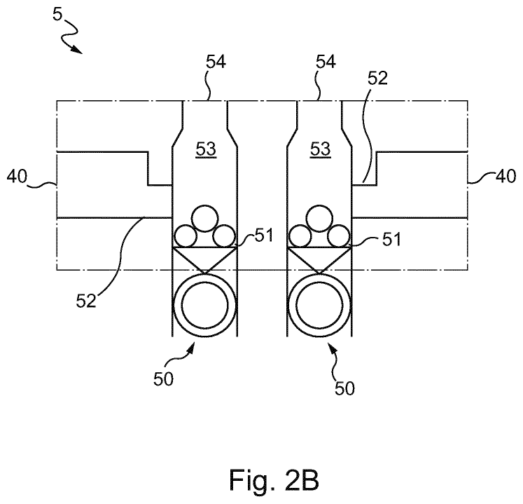

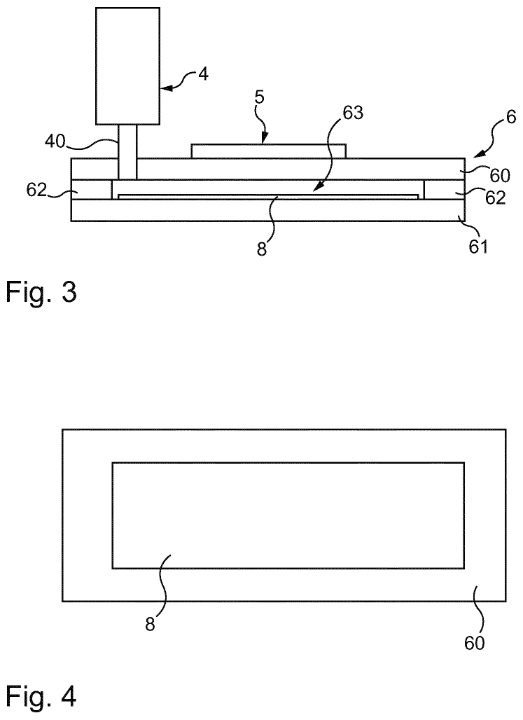

The vapor generation unit 5 comprises a micro-electro-mechanical-systems, also commonly called MEMS. The vapor generation unit 5 is integrated to a printed circuit board 6 (visible on FIGS. 2 and 3), also named here secondary printed circuit board.

The MEMS comprises at least one microfluidic structure, called a MEMS die. MEMS dies comprise a series of small chambers, each containing a heater therein.

The most significant advantage of MEMS is their ability to communicate easily with electrical elements in semiconductor chips. Other advantages include small size, compact structure, lower power consumption, lower cost, increased reliability and higher precision, and high heat transfer efficiency.

In an embodiment, the aerosol-generating device 1 can comprise more than one vapor generation unit 5. Use of a plurality of vapor generation units can help producing a sufficient quantity of aerosol and/or providing a large aerosol production surface to obtain a homogeneous aerosol.

In the present invention, the aerosolization does not involve a phase change from the aerosolizable material to gas. It generally creates an aerosol using thermal firing chambers. The working principle is similar for example to that of the thermal inkjet functioning. The aerosolizable material droplets are ejected from at least one MEMS die by applying a pulse of pressure to the material supplied in the chambers of the MEMS die.

To create this pressure pulse, “thermal inkjet” principle can be applied as follows. The aerosolizable material is heated by the heater of the at least one MEMS die until it starts to boil and a gas bubble is created. The gas bubble is comprised of a phase change of the aerosolizable material, usually liquid, and potentially air trapped in the liquid. The amount of the aerosolizable material being boiled is about 1% of the total amount. In other words, around 1% of the aerosolizable material is superheated to form a gas bubble. This 1% consists of the amount of aerosolizable material that is the closest to the heater. Gas being much more voluminous than liquid, it provides the force to push out from the vapour generation unit. This allows approximately 80-90% of the aerosolizable material above the gas bubble to be ejected.

Gas bubbles grow as they are heated until being large enough that they force liquid droplets to be ejected. The gas bubbles also escape when the liquid droplets are ejected. This creates a vacuum which causes more liquid to be drawn into the vapor generation unit 5 from the reservoir 4. The process then repeats.

It shall be noted that the propylene glycol (PG) and the vegetable glycerine (VG) that may be present in the aerosolizable material may not vaporize as boiling points of these components are higher than the boiling point of water at the same atmospheric pressure. However, because the high temperature's heater, it is very possible that all of the aerosolizable material near the heater, regardless of composition, is superheated and undergoes the phase change to the gas bubble. In other words, the 1% amount of the aerosolizable material that is superheated can be made up of a mixture of components that is similar to that of the rest of the aerosolizable material.

The vapor generation unit 5 can be permanently installed on the aerosol-generating device. Or, in another embodiment, the vapor generation unit 5 and the reservoir 4 jointly form a removable cartridge for the aerosol-generating device that can be detached (such as when the reservoir is empty of liquid).

The aerosol-generating device 1 further comprises a mouthpiece portion 7 having an aerosol outlet 70. The mouthpiece consists of the portion from which a consumer inhales the aerosol.

The aerosol-generating device 1 thus comprises an aerosol flow path (shown on FIG. 2b) extending from the vapor generation unit 5, and arranged to fluidically communicate with the mouthpiece 7 to allow the generated aerosol to flow from the vapor generation unit 5 to the mouthpiece 7. The aerosol flow path, which may also be referred to as an airflow path of the aerosol-generating device, is thus a channel through which air flows substantially in a direction towards the mouthpiece when a consumer draws upon the mouthpiece.

In this embodiment, the aerosol-generating device has an elongated shape. The mouthpiece 7 is located at one end of the aerosol-generating device. The at least one reservoir 4 is located under the vapor generation unit 5 when the aerosol generating device is in the use position. Use position shall mean the position in which is put the aerosol generating device when ready for use or being used, namely the position in which the mouthpiece 7 is upwards.

FIG. 2a represents an example of a vapor generation unit that is particularly adapted to be used in the embodiment of FIG. 1. The vapor generation unit 5 comprises here two microfluidic structures or MEMS dies 50. The two MEMS dies 50 are fastened, e.g. soldered, to the printed circuit board 6.

Each MEMS dies 50 has an upper surface 51. The two upper surfaces 51 are coplanar and thus form the upper surface of the vapor generation unit 5.

On the opposite side of the printed circuit board 6, the vapor generation unit 5 comprises two inlet ports 52. Each inlet port 52 is configured to be fluidically connected to an inner volume of the reservoir 4 of the aerosol-generating device.

FIG. 2b represents in a cross-sectional diagram a portion of an example of an aerosol-generation device comprising in a different configuration a vapor generation unit 5. The vapor generation unit 5 of FIG. 2b is similar to that of FIG. 2a and is also particularly adapted to be used in the embodiment of FIG. 1.

The vapor generation unit 5 also comprises here two microfluidic structures or MEMS dies 50. Each MEMS die 50 of the vapor generation unit 5 has an upper surface or vaporization surface 51.

The vapor generation unit 5 is in fluid communication with two liquid channels 40 each of which is arranged to transport the liquid aerosolizable material from the reservoir 4 to the vapor generation unit 5. Each liquid channel 40 is connected to a MEMS die 50 through an inlet port 52. Liquid aerosolizable material is drawn from each liquid channel 40 to a MEMS die 50 by capillary force.

Two aerosol flow paths 53 are arranged to fluidly communicate with the mouthpiece of the aerosol-generating device. Each aerosol flow path 53 allows thus the generated aerosol to flow from a MEMS die 50 of the vapor generation unit 5 to the mouthpiece. In other words, the airflow paths 53 connect air inlets (not shown) within the aerosol-generating device to the mouthpiece for the passage of air through the aerosol-generating device.

A downstream end of each aerosol flow path 53 forms a nozzle 54. The nozzles 54 and the vaporization surfaces 51 are usually on parallel planes. In other words, each nozzle 54 faces a vaporization surface 51.

Each nozzle 54 can be offset from the vaporization surface 51 or alternatively, the nozzle 54 and the vaporization surface 51 may align direction one above the other.

When a user draws on the mouthpiece 7, air is brought into the airflow paths 53 through the air inlets connected to the airflow paths 53 so as to create a pressure change that draws the generated aerosol flow to the mouthpiece as it passes over the vaporization surface 51.

In a setup where each nozzle 54 is offset from a corresponding vaporization surface 51, incoming air through the air inlets can flow sideways along the vaporization surface 51 and then pulls up from the nozzle 54. Alternatively incoming air through the air inlets can flow directly into the airflow path 53 over the vaporization surface 51. The nozzle 54 is jetting either perpendicular to, or in parallel with the airflow of the mouthpiece.

FIG. 3 represents a schematic view of the printed circuit board 6 on which is mounted the vapor generation unit 5 according to one embodiment of the invention. FIG. 3 further represents a reservoir 4 connected to the printed circuit board 6. In other words, the printed circuit board 6 is fluidically connected to the reservoir 4 and carries the vapor generation unit 5.

The printed circuit board 6 comprises at least two stacked boards and a spacer between two of said at least stacked boards. The boards and the spacer are attached to each other, for example by welding.

In the represented example, the printed circuit board 6 comprises two stacked boards. In particular, the printed circuit board 6 comprises a daughterboard 60 and a cover board 61.

The printed circuit board 6 further comprises here a spacer 62 between the daughterboard 60 and the cover board 61.

The spacer 62 is preferably made of a material adapted to withstand high temperatures. For example, the spacer 62 is made of mild steel, stainless steel or nickel-plated brass.

The spacer 62 forms with the boards a void 63 configured to receive the aerosolizable material deriving from the reservoir 4. The aerosol-generating device 1 comprises here a fluidic connection or liquid channel 40 between the reservoir 4 and the printed circuit board 6. More particularly, the channel 40 passes through the daughterboard 60 and opens to the void 63.

The void 63 presents here a rectangular parallelepiped shape. Preferably, the void presents a very small height compared to its other dimensions, such that the void 63 has a high surface area to volume ratio, preferably at least equal to 15. Height shall mean the dimension taken in the direction that is orthogonal to the boards.

The vapor generation unit 5 is mounted on the printed circuit board 6. In particular, the vapor generation unit 5 is mounted on the daughterboard 60 of the printed circuit board 6. The daughterboard 60 is configured to provide an exit for the aerosolizable material.

The aerosol-generating device 1 further comprises a heater 8. The heater 8 is fastened to the printed circuit board 6.

In particular, the heater 8 is mounted on the cover board of the printed circuit board 201.

According to an embodiment, the heater is a stratified element. For example, the heater 8 is a heating film as in FIG. 3.

Preferably, the heater 8 presents a shape and dimensions that correspond to those of the void 63.

The heater 8 comprises a resistive layer adapted to heat when power is applied to it. The battery 2 is for example adapted to heat the heater supplying power from to it.

The heater can comprise a copper layer. The copper layer thus forms the resistive layer.

The heater 8 can further comprise a coating layer. The copper layer is made of a material adapted to prevent chemical reactions with the aerosolizable material. For example, the coating layer is made of gold or silver.

In operation, the aersolizable material is drawn from the reservoirs into the printed circuit board 6.

Thanks to the fluidic connection with the reservoir 4, the aerosolizable material is thus in contact with the printed circuit board 6 after it derives from the reservoir 4. In particular, the aerosolizable material passes through the void 63 before entering into the vapor generation unit 5.

Thanks to power supplied by the battery 2, the heater 8 is heated. In turn, the heater heats the aerosolizable material passing through the printed circuit board 6.

The matching between the shape and dimensions of the heater 8 and those of the void 63 enable an optimized heating of the aerosolizable material. This is even improved here with the high surface area to volume ratio of the void 63.

Therefore, thanks to this configuration, there is no need to dispose a heater in the reservoir 4 to heat the aerosolizable material. This configuration provides thus a compact solution.

The hot aerosolizable material then exists the printed circuit board to pass into and through the vapor generation unit 5. The vapor generation unit 5 finally transforms the aerosolizable material into aerosol.

The aerosol generated by the vapor generation unit 5 finally enters the airflow channel of the aerosol-generating device and travels to the mouthpiece 7.

Thanks to this configuration of the aerosol-generating device 1, the aerosol generated by the aerosol-generating device 1 is warm.

It should be understood that various changes and modifications to the presently preferred embodiments described herein will be apparent to those skilled in the art. Such changes and modifications can be made without departing from the spirit and scope of the present invention and without diminishing its attendant advantages. It is therefore intended that such changes and modifications be covered by the appended claims.

The present invention thus provides a compact and inexpensive aerosol-generating device comprising a vapor generation unit benefiting therefore from the advantages provided by the MEMS technology while enabling the consumer to inhale a warm aerosol.

### REFERENCES USED FOR THE FIGURES

| | |
|---|---|
| 1 | Aerosol-generating device |
| 2 | Battery |
| 3 | Main printed circuit board |
| 4 | Reservoir |
| 40 | Channel |
| 5 | Vapor generation unit |
| 50 | Microfluidic structure (MEMS die) |
| 51 | Upper surface (of a MEMS die) |
| 52 | Inlet port |
| 53 | Aerosol flow path |
| 54 | Nozzle |
| 6 | Printed circuit board |
| 60 | Daughterboard |
| 61 | Cover board |
| 62 | Spacer |
| 63 | Void |
| 7 | Mouthpiece |
| 70 | Aerosol outlet |
| 8 | Heater |

1. An aerosol-generating device comprising a vapor generation unit and a reservoir configured to store an aerosolizable material, the vapor generation unit comprising a micro electro-mechanical system (MEMS), wherein the aerosol-generating device further comprises a printed circuit board and a heater fastened to said printed circuit board, the printed circuit board being disposed such that the aerosolizable material is configured to be in contact with said printed circuit board after the aerosolizable material derives from the reservoir and before the aerosolizable material arrives to the vapor generation unit, the printed circuit board comprising at least two stacked boards and a spacer between two of said at least two stacked boards, said at least two stacked boards and said spacer being attached to each other so as to form a void configured to receive the aerosolizable material deriving from the reservoir.

2. The aerosol-generating device according to claim 1, wherein the heater comprises a resistive layer adapted to be heated when power is applied to the resistive layer.

3. The aerosol-generating device according to claim 1, wherein the heater is a heating film.

4. The aerosol-generating device according to claim 1, wherein the heater comprises a coating layer made of a material adapted to prevent chemical reactions with the aerosolizable material.

5. The aerosol-generating device according to claim 4, wherein the coating layer is made of gold or silver.

6. The aerosol-generating device according to claim 1, wherein the vapor generation unit is mounted on the printed circuit board.

7. The aerosol-generating device according to claim 1, wherein the heater matches dimensions and a shape of said void.

8. The aerosol-generating device according to claim 1, wherein the at least two stacked boards comprise a daughterboard and a cover board.

9. The aerosol-generating device according to claim 8, wherein the heater is mounted on the cover board.

10. The aerosol-generating device according to claim 8, wherein the vapor generation unit is mounted on the daughterboard, the daughterboard being configured to provide an exit for the aerosolizable material.
